(19) United States
(12) Patent Application Publication
(10) Pub. No.: US 2018/0011356 A1
(43) Pub. Date: Jan. 11, 2018

(54) ARRAY SUBSTRATE AND MANUFACTURING METHOD THEREOF, DISPLAY DEVICE AND MANUFACTURING METHOD THEREOF

(71) Applicant: BOE Technology Group Co, Ltd., Beijing (CN)

(72) Inventor: Xiangyong KONG, Beijing (CN)

(21) Appl. No.: 15/547,410

(22) PCT Filed: Apr. 15, 2016
(86) PCT No.: PCT/CN2016/079359

§ 371 Date: Jul. 28, 2017

(30) Foreign Application Priority Data
Jun. 4, 2015 (CN) 201510303519.1

(51) Int. Cl. G02F 1/1368; G02F 1/1343; H01L 27/12

(52) U.S. Cl. CPC G02F 1/1368; H01L 27/1262; G02F 1/1343; H01L 27/1225; H01L 27/1255

(57) ABSTRACT

The present disclosure discloses an array substrate, a display device and manufacturing methods thereof. The array substrate comprises: a base, a gate metal layer, an active layer, a source/drain metal layer, and a pixel electrode layer, wherein the array substrate has a storage capacitor region; in the storage capacitor region, the gate metal layer, the active layer, the source/drain metal layer and the pixel electrode layer comprise respective patterns; wherein, the projections of the gate metal layer storage pattern, the active layer storage pattern, the source/drain metal layer storage pattern, and the pixel electrode layer storage pattern on the base at least partially overlap, and the pixel electrode layer storage pattern is electrically connected to the gate metal layer storage pattern to form a first electrode of the storage capacitor, the active layer storage pattern is electrically connected to the source/drain metal layer storage pattern to form a second electrode.

### CROSS-REFERENCE TO RELATED APPLICATION

This application claims the benefit and priority of Chinese Patent Application No. 201510303519.1, filed on Jun. 4, 2015, the entire content of which is incorporated by reference herein.

### FIELD OF THE INVENTION

The present disclosure relates to a field of display technologies, and more particularly, to an array substrate and a manufacturing method thereof, a display device and a manufacturing method thereof.

### BACKGROUND

In recent years, the display technology has been developed rapidly. For example, the Thin Film Transistor (referred to as TFT) technology has been developed from the original amorphous silicon thin film transistor to the current low-temperature polysilicon thin film transistor, metal oxide semiconductor thin film transistor and the like. Further, the light-emitting technology has been developed from the original Liquid Crystal Display (referred to as LCD) technology to the current Organic Light-Emitting Diode (referred to as OLED) technology.

According to the principle of the liquid crystal display, thin film transistors located in the same row are turned on at the same time by controlling an input signal of a gate line. After a certain period of time, the next row of thin film transistors are turned on at the same time, and so on. However, since each row of thin film transistors are turned on for a relatively short time, it is hard to reach LCD response time, therefore, a liquid crystal display might flicker. To avoid such problem, currently, a storage capacitor is generally used to prevent the liquid crystal display from flickering. Thus, in a certain period of time after thin film transistors are turned off, the storage capacitor can be used to maintain the voltage of a pixel electrode, thereby providing time for liquid crystals to respond.

Currently, in order to meet the requirements for high resolution of a liquid crystal display panel, pixel size is made smaller and smaller, resulting in a reduction of the storage capacitor and unenough time for liquid crystals to respond, and the occurrence of flickering, seriously affecting the display effect. However, if to increase the storage capacitor, a larger area occupied by the storage capacitor might affect the pixel aperture ratio.

### BRIEF SUMMARY OF THE INVENTION

In view of the drawbacks of the prior art, the present disclosure provides an array substrate and a manufacturing method thereof, a display device and a manufacturing method thereof.

In a first aspect, the present disclosure provides an array substrate, comprising: a base, a gate metal layer, an active layer, a source/drain metal layer, and a pixel electrode layer, wherein, the array substrate has a storage capacitor region. In the storage capacitor region, the gate metal layer comprises a gate metal layer storage pattern; the active layer comprises an active layer storage pattern; the source/drain metal layer comprises a source/drain metal layer storage pattern; and the pixel electrode layer comprises a pixel electrode layer storage pattern. Wherein, the projections of the gate metal layer storage pattern, the active layer storage pattern, the source/drain metal layer storage pattern, and the pixel electrode layer storage pattern on the base at least partially overlap, the pixel electrode layer storage pattern is electrically connected to the gate metal layer storage pattern to form a first electrode of the storage capacitor, and the active layer storage pattern is electrically connected to the source/drain metal layer storage pattern to form a second electrode of the storage capacitor.

Alternatively, the active layer is provided on the gate metal layer, the source/drain metal layer is provided on the active layer, and the pixel electrode layer is provided on the source/drain metal layer. The array substrate further comprises: a gate insulating layer provided between the gate metal layer and the active layer, an etching barrier layer provided between the active layer and the source/drain metal layer, and a passivation layer provided between the source/drain metal layer and the pixel electrode layer.

Alternatively, in the storage capacitor region, the pixel electrode layer storage pattern is electrically connected to the gate metal layer storage pattern through a first via in the passivation layer, the etching barrier layer and the gate insulating layer.

The source/drain metal layer storage pattern is electrically connected to the active layer storage pattern through a second via in the etching barrier layer.

Alternatively, the active layer storage pattern in the storage capacitor region is an active layer storage pattern after plasma processing or ion injection.

In an embodiment, the gate insulating layer, the etching barrier layer, and the passivation layer respectively comprise at least one of silicon oxide, silicon nitride, hafnium oxide, silicon oxynitride, and aluminum oxide; the base comprises at least one of a glass substrate, a quartz substrate, and an organic resin substrate.

The gate metal layer comprises at least one of molybdenum, molybdenum niobium alloy, aluminum, aluminum neodymium alloy, titanium and copper.

The active layer comprises a transparent metal oxide semiconductor.

The source/drain metal layer comprises at least one of molybdenum, molybdenum niobium alloy, aluminum, aluminum neodymium alloy, titanium and copper;

The pixel electrode layer comprises a transparent conductive metal oxide.

In a second aspect, the present disclosure further provides a method of manufacturing an array substrate, comprising: forming a gate metal layer, an active layer, a source/drain metal layer, and a pixel electrode layer on a base, wherein, the array substrate has a storage capacitor region. Wherein, in the storage capacitor region, the gate metal layer comprises a gate metal layer storage pattern, the active layer comprises an active layer storage pattern, the source/drain metal layer comprises a source/drain metal layer storage pattern, and the pixel electrode layer comprises a pixel electrode layer storage pattern. And wherein, the projections of the gate metal layer storage pattern, the active layer storage pattern, the source/drain metal layer storage pattern, and the pixel electrode layer pattern on the base at least partially overlap, the pixel electrode layer storage pattern is electrically connected to the gate metal layer storage pattern to form a first electrode of the storage capacitor, and the active layer storage pattern is electrically connected to the source/drain metal layer storage pattern to form a second electrode of the storage capacitor.

Alternatively, the method further comprises: providing the active layer on the gate metal layer, providing the source/drain metal layer on the active layer, and providing the pixel electrode layer on the source/drain metal layer, wherein, the method further comprises:

forming a gate insulating layer between the gate metal layer and the active layer, forming an etching barrier layer between the active layer and the source/drain metal layer, and forming a passivation layer between the source/drain metal layer and the pixel electrode layer.

Alternatively, a plasma processing or an ion injection is performed on the active layer storage pattern preformed in the storage capacitor region before the etching barrier layer is formed.

Alternatively, after the passivation layer is formed, a first via is formed in the passivation layer, the etching barrier layer, and the gate insulating layer, to electrically connect the pixel electrode layer storage pattern to the gate metal layer storage pattern of the storage capacitor region.

Alternatively, after the etching barrier layer is formed, a second via is formed in the etching barrier layer to electrically connect the source/drain metal layer storage pattern to the active layer storage pattern of the storage capacitor region.

In an embodiment, the gate insulating layer, the etching barrier layer and the passivation layer respectively comprise at least one of silicon oxide, silicon nitride, hafnium oxide, silicon oxynitride, and aluminum oxide. The base comprises at least one of a glass substrate, a quartz substrate and an organic resin substrate. The gate metal layer comprises at least one of molybdenum, molybdenum niobium alloy, aluminum, aluminum neodymium alloy, titanium and copper. The active layer comprises a transparent metal oxide semiconductor. The source/drain metal layer comprises at least one of molybdenum, molybdenum niobium alloy, aluminum, aluminum neodymium alloy, titanium and copper. The pixel electrode layer comprises a transparent conductive metal oxide.

In a third aspect, the present disclosure further provides a display device comprising the above-described array substrate.

In a fourth aspect, the present disclosure further provides a method of manufacturing the display device, comprising a method of manufacturing the above-described array substrate.

### BRIEF DESCRIPTION OF THE DRAWINGS

To more clearly illustrate the technical solutions of the embodiments of the present invention, the drawings of the embodiments will be briefly described below. It will be apparent that the drawings in the following description are merely illustrative of some embodiments of the invention and are not intended to limit the invention.

FIGS. 1 to 9 are schematic diagrams of a process for manufacturing an array substrate provided in an embodiment of the present disclosure;

FIG. 10 is schematic diagram showing an example embodiment of a display device.

### DETAILED DESCRIPTION

Unless expressly stated otherwise in the context, the singular form of a word used in the description and appended claims comprises the plural form thereof, and vice versa. Thus, when the singular form of a term is referred to, the corresponding plural form is usually included. Similarly, the words “comprising” and “including” will be construed as being inclusive rather than exclusive. Likewise, the words “comprising” and “or” should be construed as being inclusive unless expressly prohibited otherwise in the context. When the term “instance” or “example” is used herein, particularly when it is located after a set of terms, the “instance” or “example” is merely exemplary and illustrative, and should not be considered exclusive or comprehensive.

The present disclosure provides an array substrate, which is shown in FIG. 9, comprising: a base 1, a gate metal layer 2, an active layer 4, a source/drain metal layer 9, a pixel electrode layer 11, and a storage capacitor region. In the storage capacitor region, the gate metal layer 2 comprises a gate metal layer storage pattern 22, the active layer 4 comprises an active layer storage pattern 42, the source/drain metal layer 9 comprises a source/drain metal layer storage pattern 93, and the pixel electrode layer 11 comprises a pixel electrode layer storage pattern 112. Wherein, the projections of the gate metal layer storage pattern 22, the active layer storage pattern 42, the source/drain metal layer storage pattern 93, and the pixel electrode layer storage pattern 112 on the base 1 at least partially overlap, the pixel electrode layer storage pattern 112 is electrically connected to the gate metal layer storage pattern 22 to form a first electrode of the storage capacitor, and the active layer storage pattern 42 is electrically connected to the source/drain metal layer storage pattern 93 to form a second electrode of the storage capacitor.

The storage capacitor is arranged in the array substrate by way of connecting two storage capacitors in parallel, wherein, the gate metal layer storage pattern 22 and the active layer storage pattern 42 form a storage capacitor, the source/drain metal layer storage pattern 93 and the pixel electrode layer storage pattern 112 form another storage capacitor, and the two storage capacitors are connected in parallel in the same storage capacitor region, the projections thereof on the base are overlapping, thereby reducing the area occupied by the two parallel storage capacitors and improving the pixel aperture ratio.

To form the two storage capacitors, the array substrate further comprises: a gate insulating layer 3 provided between the gate metal layer 2 and the active layer 4, an etching barrier layer 8 provided between the active layer 4 and the source/drain metal layers 9, and a passivation layer 10 provided between the source/drain metal layer 9 and the pixel electrode layer 11.

It is to be understood that the gate insulating layer 3, the etching barrier layer 8 and the passivation layer 10 are insulating, and may be made of a multilayer composite film including one or two of silicon oxide (SiOₓ), silicon nitride (SiNₓ), hafnium oxide (HfOₓ), silicon oxynitride (SiON), AlOₓ, and the like. For example, the two-layer structure of the passivation layer 10 may be a laminate structure of SiNₓ/SiOₓ, and may also be a laminate structure of SiNₓ/SiON/SiOₓ, the total thickness of the film layer may be controlled at about 100 to 600 nm, and the thickness of each film layer may be adjusted according to the actual situation. The gate insulating layer 3 and the etching barrier layer 8 above-mentioned are similar to the passivation layer 10, and will not be described in detail in this embodiment.

When the first electrode and the second electrode of the storage capacitor are being formed, for example, in the storage capacitor region, the pixel electrode layer storage pattern 112 is electrically connected to the gate metal layer storage pattern 22 through the first via 12 through the passiviation layer 10, the etching barrier layer 8 and the gate insulating layer 3; the source/drain metal layer storage pattern 93 is electrically connected to the active layer storage pattern 42 through the second via 13 in the etching barrier layer 8.

It is to be noted that since the active layer 4 is made of an oxide semiconductor, to enable the active layer storage pattern 42 formed by the active layer 4 to serve as an electrode of the storage capacitor, it is to be understood that the active layer storage pattern 42 is processed as the active layer storage pattern of a conductor after plasma processing or ion injection.

Further provided in the embodiments of the present disclosure is a method of manufacturing an array substrate, the method comprising: forming on a base 1 a gate metal layer 2, an active layer 4, a source/drain metal layer 9, a pixel electrode layer 11, and a storage capacitor region. Wherein, in the storage capacitor region, the gate metal layer 2 comprises a gate metal layer storage pattern 22, the active layer 4 comprises an active layer storage pattern 42; the source/drain metal layer 9 comprises a source/drain metal layer storage pattern 93; and the pixel electrode layer 11 comprises a pixel electrode layer storage pattern 112; the projections of the gate metal layer storage pattern 22, the active layer storage pattern 42, the source/drain metal layer storage pattern 93 and the pixel electrode layer storage pattern 112 on the base 1 at least partially overlap, the pixel electrode layer storage pattern 112 is electrically connected to the gate metal layer storage pattern 22 to form a first electrode of the storage capacitor, and the active layer storage pattern 42 is electrically connected to the source/drain metal layer storage pattern 93 to form a second electrode of the storage capacitor.

In the above method, the storage capacitor is formed in the storage capacitor region by connecting two storage capacitors in parallel. Wherein, the gate metal layer storage pattern 22 and the active layer storage pattern 42 form a storage capacitor, the source/drain metal layer storage pattern 93 and the pixel electrode layer storage pattern 112 form another storage capacitor, and the projections of the two storage capacitors in the same storage capacitor region on the base overlap, thereby reducing the area occupied by the two parallel storage capacitors and increasing the pixel aperture ratio.

The process of the method of manufacturing the array substrate above-described will be described below in detail with reference to specific embodiments. The flow of the method of manufacturing the array substrate may include the following steps:

Step S1, forming the gate metal layer 2 on the base 1, as shown in FIG. 1.

For example, the base 1 may be a glass substrate, a quartz substrate, or an organic resin substrate; the material of the gate metal layer 2 may be a monolayer or multilayer composite laminate formed by one or more of molybdenum (Mo), molybdenum niobium alloy (MoNb), aluminum (Al), aluminum neodymium alloy (AlNd), titanium (Ti) and copper (Cu), preferably a monolayer or multilayer composite film including Mo, Al or an alloy containing Mo and Al. In an embodiment, the thickness is from 100 nm to 500 nm.

The gate metal layer 2 may be formed by depositing a gate metal layer on the base 1 by sputtering or thermal evaporation.

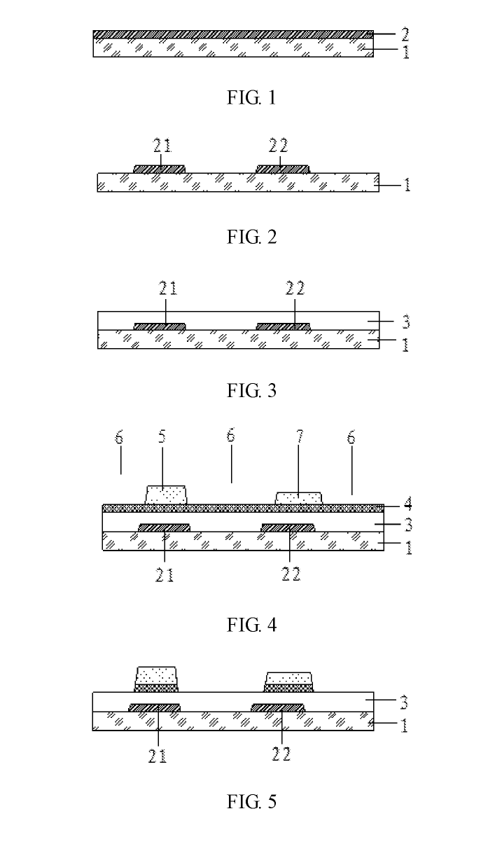

Step S2, forming the gate pattern 21 and the gate metal layer storage pattern 22 by a one patterning process, as shown in FIG. 2.

The above patterning process can be understood as follows: coating a layer of photoresist on the gate metal layer 2 deposited in step S1 above, exposing and developing the coated photoresist with a mask, then removing the gate metal layer 2 in a non-photoresist region with mixing an acid solution, and finally peeling off the photoresist to form the gate pattern 21 and the gate metal layer storage pattern 22, as shown in FIG. 2.

Step S3, depositing the gate insulating layer 3 on the gate pattern 21, the gate metal layer storage pattern 22 and the base 1, as shown in FIG. 3.

In the present embodiment, the material of the gate insulating layer 3 may include a multi-layer composite film including one or two of silicon oxide (SiOₓ), silicon nitride (SiNₓ), hafnium oxide (HfOₓ), silicon oxynitride (SiON), AlOₓ. The gate insulating layer 3 is manufactured by Plasma Enhanced Chemical Vapor Deposition (PECVD). In the manufacturing process, it is necessary to control the hydrogen content of the film layer at a low level. For example, the second-generation structure of the gate insulating layer may be a laminate structure of SiNₓ/SiOₓ or be a laminate structure of SiNₓ/SiON/SiOₓ. The total thickness of the film layer can be controlled at about 100 to 600 nm, and the thickness of each film layer can be adjusted according to the actual situation.

Step S4, depositing the active layer 4 on the gate insulating layer 3, and depositing a photoresist on the active layer 4.

The material of the active layer may include at least one of transparent metal oxide semiconductor materials, such as Indium Gallium Zinc Oxide (IGZO), Indium Tin Zinc Oxide (ITZO), indium oxide (In₂O₃), zinc oxide (ZnO), and the like, and the thickness thereof can be controlled at 10 to 150 nm.

Step S5, forming a completely-exposed region, an unexposed region, and a grayscale-exposed region with a grayscale mask by exposure and developing processes, removing the photoresist in the completely-exposed region (photoresist completely-removed region 6) and part of the photoresist in the grayscale-exposed region (photoresist semi-retained region 7), as shown in FIG. 4.

It will be appreciated that the grayscale mask includes a completely opaque portion, a translucent portion and a completely transparent portion. That is, the grayscale mask plate is for forming an opaque shielding metal layer in some regions on the transparent base material, a semi-transparent shielding metal layer in some other regions, and without forming any shielding metal layer in the remaining regions. Wherein, the thickness of the semi-transparent shielding metal layer is smaller than the thickness of the completely opaque shielding metal layer. In addition, the transmittance of the semi-transparent shielding metal layer to ultraviolet light can also be changed by adjusting the thickness of the semi-transparent shielding metal layer.

On this basis, the working principle of the grayscale mask plate is as follows: by controlling the thickness of the shielding metal layer in different regions of the grayscale mask plate, making the intensity of the transmitted light exposed to different regions different, so as to form, after selectively exposing and developing the photoresist, an unexposed region, a grayscale unexposed region, and a completely-exposed region, which respectively correspond to the completely opaque portion, the translucent portion, and the completely transparent portion of the grayscale mask plate.

The photoresist referred to in the present embodiment is a positive photoresist and may be a light-sensitive mixed liquid including three main components, a photosensitive resin, a sensitizer and a solvent. After the photoresist is exposed to light, a photocurable reaction can occur quickly in the exposed region, and the cured photosensitive resin can be washed off subsequently by a specific solution.

Step S6, etching the active layer 4 corresponding to the completely-exposed region, as shown in FIG. 5.

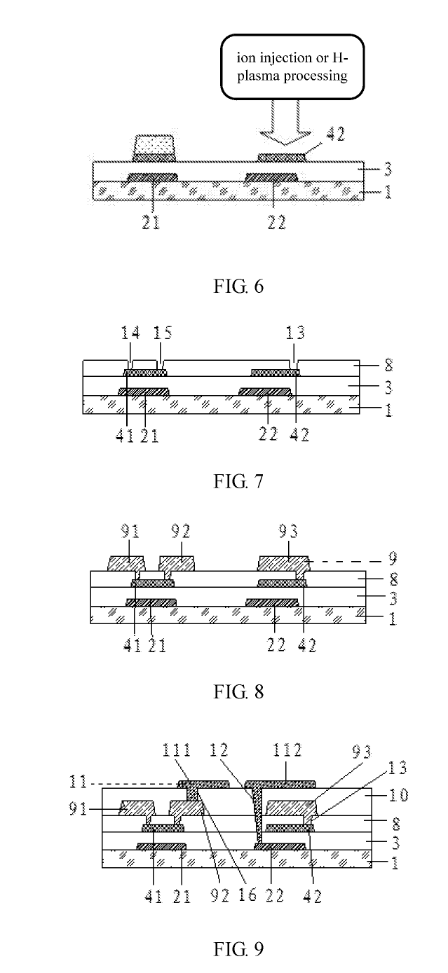

Step S7, peeling off the photoresist in the grayscale-exposed region, and processing the semiconductor of the exposed active layer storage pattern preformed as the active layer storage pattern 42 of the conductor after plasma processing (H-plasma processing) or ion injection, as shown in FIG. 6.

The photoresist in the grayscale-exposed region may be peeled off by the etching method, and may be peeled off by a second exposure and development with the grayscale mask plate, while the present embodiment does not limit the specific embodiments thereof.

Step S8, removing the photoresist in the unexposed region (photoresist completely-retained region 5), forming the active layer pattern 41, forming the etching barrier layer 8 on the active layer pattern 41 and the active layer storage pattern 42, and forming the second via 13, the third via 14 and the fourth via 15 by a one-time patterning process, as shown in FIG. 7.

It is to be understood that the above-described patterning process is similar to step S2, and will not be described in detail in the present embodiment.

In addition, the second via 13 above-mentioned may be understood as a via preformed as an electrode of the storage capacitor, the third via 14 and the fourth via 15 may be understood to be vias formed at positions opposite to the active layer pattern 41 to electrically connect the active layer pattern 41 to the source pattern 91 and the drain pattern 92.

Step S9, depositing the source/drain metal layer 9 on the etching barrier layer 8, and forming the source pattern 91, the drain pattern 92 and the source/drain metal layer storage pattern 93 by a one-time patterning process, as shown in FIG. 8.

The material of the source/drain metal layer 9 may be a monolayer or multi-layer composite laminate including one or more of molybdenum (Mo), molybdenum niobium alloy (MoNb), aluminum (Al), aluminum neodymium alloy (AlNd), titanium (Ti) and copper (Cu), preferably a monolayer or multi-layer composite film including Mo, Al or an alloy containing Mo and Al.

Wherein, the patterning process for forming the source pattern 91, the drain pattern 92 and the source/drain metal layer storage pattern 93 may be similar to step S2, and will not be described in detail in the present embodiment.

It is to be understood that the positions of the source pattern 91 and the drain pattern 92 are also interchangeable, and the positions are different depending on the flow direction of the current.

Step S10, depositing the passivation layer 10, and after forming the passivation layer 10, forming the first via 12 in the passivation layer 10, the etching barrier layer 8 and the gate insulating layer 3, to electrically connecting the pixel electrode layer storage pattern 112 to the gate metal layer storage pattern 22 of the storage capacitor region.

The material of the passivation layer 10 may include a multi-layer composite film including one or two of silicon oxide (SiOₓ), silicon nitride (SiNₓ), hafnium oxide (HfOₓ), silicon oxynitride oxynitride(SiON), AlOₓ, and the like. The passivation layer 10 is manufactured by Plasma Enhanced Chemical Vapor Deposition PECVD, and it is necessary to control the hydrogen content of the film layer at a low level during the manufacturing process. For example, the two-layer structure of the passivation layer 10 may be a SiNₓ/SiOₓ laminate structure, and may also be a SiNₓ/SiON/SiOₓ laminate structure. The total thickness of the film layer may be controlled at about 100 to 600 nm, and the thickness of each film layer may be adjusted according to the actual situation.

Step S11, forming the pixel electrode layer 11, and forming the pixel electrode pattern 111 and the pixel electrode layer storage pattern 112 by a one-time patterning process, as shown in FIG. 9.

The pixel electrode layer 11 may be a transparent conductive metal oxide such as ITO, IZO or the like, and may be deposited by sputtering. The deposition thickness of the pixel electrode layer 11 may be 40 to 200 nm.

The patterning process for forming the pixel electrode pattern 111 and the pixel electrode layer storage pattern 112 may be similar to step S2, which will not be described in detail in the present embodiment.

It is to be understood that, in the process of manufacturing the array substrate, each of the layers such as the gate metal layer 2, the gate insulating layer 3, the active layer 4, the etching barrier layer 8, the source/drain metal layer 9, the passivation layer 10, the pixel electrode layer 11 and the like can be formed by vacuum deposition or magnetron sputtering, which will not be described in detail in the present embodiment.

In addition, it should be understood that the pixel electrode layer 11 may be understood as a layer comprising a gate pattern 21 and a gate metal layer storage pattern 22 or preformed with a gate pattern 21 and a gate metal layer storage pattern 22; the active layer 4 mas a layer comprising an active layer pattern 41 and an active layer storage pattern 42, or preformed with an active layer pattern 41 and an active layer storage pattern 42; the source/drain metal layer as a layer comprising a source layer 91, a drain pattern 92 and a source/drain metal layer storage pattern 93, or preformed with a source layer 91, a drain pattern 92 and a source/drain metal layer storage pattern 93; the pixel electrode layer as a layer comprising a pixel electrode pattern 111 and a pixel electrode layer storage pattern 112 or preformed with a pixel electrode pattern 111 and a pixel electrode layer stores pattern 112.

The present embodiment further provides a display device comprising an array substrate as described above.

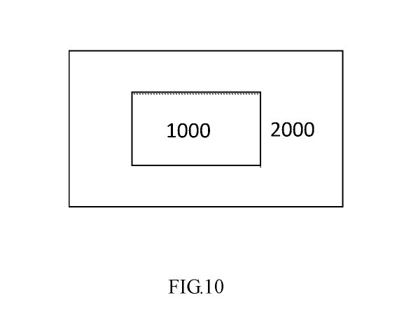

FIG. 10 is schematic diagram showing an example embodiment of a display device. In this example embodiment, a display device 2000 includes an array substrate 1000, and the 1000 is an array substrate as shown in FIGS. 1-9.

The display device in the present embodiment may be any product or component having a display function such as a mobile phone, a tablet computer, a television set, a notebook computer, a digital photo frame, a navigator, or the like.

A number of specific details are set forth in the description of the present disclosure. However, it will be understood that embodiments of the present disclosure may be practiced without these specific details. In some instances, well-known methods, structures, and techniques have not been shown in detail so as not to obscure the understanding of this specification.

The technical or scientific terms used in the present disclosure should be of ordinary interest to those of ordinary skill in the art to which the present disclosure belongs. “First”, “second” and similar words used in the present disclosure do not denote any order, quantity or importance, but are merely used to distinguish between different constituents. Similarly, similar words such as “one”, “a” or “the” do not represent a quantity limit, but rather that there is at least one. Similar words such as “comprising” and “including” mean that the element or object preceding a word covers the elements or objects and their equivalents listed following the word, without excluding other elements or objects. “Connected”, “attached” and the like are not limited to a physical or mechanical connection, but may comprise an electrical connection, whether direct or indirect. “Upper”, “lower”, “left”, “right” and the like are used only to represent the relative positional relationship, which may be changed accordingly when the absolute position of the object to be described is changed.

Finally, it should be noted that the above embodiments are merely illustrative of the technical solutions of the present disclosure and are not intended to be limiting thereof Although the present disclosure has been described in detail with reference to the foregoing embodiments, those of ordinary skill in the art will understand that it is still possible to modify the technical solutions described in the foregoing embodiments or to replace some or all of the technical features therein equivalently, and that these modifications or substitutions do not depart the essence of the corresponding technical solutions from the scope of the technical solutions in the embodiments of the present disclosure and they shall all be encompassed in the scope of the claims and description of the present disclosure.

1. An array substrate, comprising: a base, a gate metal layer, an active layer, a source/drain metal layer, and a pixel electrode layer, wherein the array substrate has a storage capacitor region;
and wherein, in the storage capacitor region, the gate metal layer comprises a gate metal layer storage pattern, the active layer comprises an active layer storage pattern, the source/drain metal layer comprises a source/drain metal layer storage pattern, and the pixel electrode layer comprises a pixel electrode layer storage pattern;
wherein, the projections of the gate metal layer storage pattern, the active layer storage pattern, the source/drain metal layer storage pattern, and the pixel electrode layer storage pattern on the base at least partially overlap, and the pixel electrode layer storage pattern is electrically connected to the gate metal layer storage pattern to form a first electrode of the storage capacitor, the active layer storage pattern is electrically connected to the source/drain metal layer storage pattern to form a second electrode of the storage capacitor.

2. The array substrate according to claim 1, wherein, the active layer is provided on the gate metal layer, the source/drain metal layer is provided on the active layer, the pixel electrode layer is provided on the source/drain metal layer, and wherein,
the array substrate further comprises: a gate insulating layer provided between the gate metal layer and the active layer, an etching barrier layer provided between the active layer and the source/drain metal layer, and a passivation layer provided between the source/drain metal layer and the pixel electrode layer.

3. The array substrate according to claim 2, wherein, in the storage capacitor region, the pixel electrode layer storage pattern is electrically connected to the gate metal layer storage pattern through a first via in the passivation layer, the etching barrier layer and the gate insulating layer;
the source/drain metal layer storage pattern is electrically connected to the active layer storage pattern through a second via in the etching barrier layer.

4. The array substrate according to claim 1, wherein, the active layer storage pattern in the storage capacitor region is an active layer storage pattern after plasma processing or ion injection.

5. The array substrate according to claim 2, wherein,
the gate insulating layer, the etching barrier layer, and the passivation layer respectively comprise at least one of silicon oxide, silicon nitride, hafnium oxide, silicon oxynitride, and aluminum oxide; the base comprises at least one of a glass substrate, a quartz substrate, and an organic resin substrate;
the gate metal layer comprises at least one of molybdenum, molybdenum niobium alloy, aluminum, aluminum neodymium alloy, titanium and copper;
the active layer comprises a transparent metal oxide semiconductor;
the source/drain metal layer comprises at least one of molybdenum, molybdenum niobium alloy, aluminum, aluminum neodymium alloy, titanium and copper;
the pixel electrode layer comprises a transparent conductive metal oxide.

6. A method of manufacturing an array substrate, comprising: forming a gate metal layer, an active layer, a source/drain metal layer, and a pixel electrode layer on a base, wherein the array substrate has a storage capacitor region;
wherein, in the storage capacitor region, the gate metal layer comprises a gate metal layer storage pattern, the active layer comprises an active layer storage pattern, the source/drain metal layer comprises a source/drain metal layer storage pattern, and the pixel electrode layer comprises a pixel electrode layer storage pattern,
and wherein, the projections of the gate metal layer storage pattern, the active layer storage pattern, the source/drain metal layer storage pattern, and the pixel electrode layer storage pattern on the base at least partially overlap, and the pixel electrode layer storage pattern is electrically connected to the gate metal layer storage pattern to form a first electrode of the storage capacitor, and the active layer storage pattern is electrically connected to the source/drain metal layer storage pattern to form a second electrode of the storage capacitor.

7. The method according to claim 6, further comprising providing the active layer on the gate metal layer, providing the source/drain metal layer on the active layer, and providing the pixel electrode layer on the source/drain metal layer, and wherein the method further comprises:
forming a gate insulating layer between the gate metal layer and the active layer, forming an etching barrier layer between the active layer and the source/drain metal layer, and forming a passivation layer between the source/drain metal layer and the pixel electrode layer.

8. The method according to claim 7, further comprising, performing a plasma processing or an ion injection processing on the active layer storage pattern preformed in the storage capacitor region before forming the etching barrier layer.

9. The method according to claim 7, further comprising, after forming the passivation layer, forming a first via in the passivation layer, the etching barrier layer, and the gate insulating layer to electrically connect the pixel electrode layer storage pattern to the gate metal layer storage pattern of the storage capacitor region.

10. The method according to claim 7, further comprising, after forming the etching barrier layer, a second via is formed in the etching barrier layer to electrically connect the source/drain metal layer storage pattern to the active layer storage pattern of the storage capacitor region.

11. The method according to claim 7, wherein, the gate insulating layer, the etching barrier layer and the passivation layer respectively comprise at least one of silicon oxide, silicon nitride, hafnium oxide, silicon oxynitride, and aluminum oxide;
the base comprises at least one of a glass substrate, a quartz substrate and an organic resin substrate;
the gate metal layer comprises at least one of molybdenum, molybdenum niobium alloy, aluminum, aluminum neodymium alloy, titanium and copper;
the active layer comprises a transparent metal oxide semiconductor;
the source/drain metal layer comprises at least one of molybdenum, molybdenum niobium alloy, aluminum, aluminum neodymium alloy, titanium and copper;
the pixel electrode layer comprises a transparent conductive metal oxide.

12. A display device comprising the array substrate according to claim 1.

13. A method of manufacturing a display device, comprising the method of manufacturing an array substrate according to claim 6.

14. The array substrate according to claim 2, wherein, the active layer storage pattern in the storage capacitor region is an active layer storage pattern after plasma processing or ion injection.

15. The array substrate according to claim 3, wherein, the active layer storage pattern in the storage capacitor region is an active layer storage pattern after plasma processing or ion injection.

16. The array substrate according to claim 3, wherein,
the gate insulating layer, the etching barrier layer, and the passivation layer respectively comprise at least one of silicon oxide, silicon nitride, hafnium oxide, silicon oxynitride, and aluminum oxide; the base comprises at least one of a glass substrate, a quartz substrate, and an organic resin substrate;
the gate metal layer comprises at least one of molybdenum, molybdenum niobium alloy, aluminum, aluminum neodymium alloy, titanium and copper;
the active layer comprises a transparent metal oxide semiconductor;
the source/drain metal layer comprises at least one of molybdenum, molybdenum niobium alloy, aluminum, aluminum neodymium alloy, titanium and copper;
the pixel electrode layer comprises a transparent conductive metal oxide.

17. The array substrate according to claim 4, wherein,
the gate insulating layer, the etching barrier layer, and the passivation layer respectively comprise at least one of silicon oxide, silicon nitride, hafnium oxide, silicon oxynitride, and aluminum oxide; the base comprises at least one of a glass substrate, a quartz substrate, and an organic resin substrate;
the gate metal layer comprises at least one of molybdenum, molybdenum niobium alloy, aluminum, aluminum neodymium alloy, titanium and copper;
the active layer comprises a transparent metal oxide semiconductor;
the source/drain metal layer comprises at least one of molybdenum, molybdenum niobium alloy, aluminum, aluminum neodymium alloy, titanium and copper;
the pixel electrode layer comprises a transparent conductive metal oxide

18. A display device comprising the array substrate according to claim 2.

19. A display device comprising the array substrate according to claim 3.

20. A display device comprising the array substrate according to claim 4.
